(19) United States
(12) Patent Application Publication
(10) Pub. No.: US 2005/0139259 A1
(43) Pub. Date: Jun. 30, 2005

(54) Transformerless power conversion in an inverter for a photovoltaic system

(76) Inventors: Robert Steigerwald, Burnt Hills, NY (US); Michael De Rooij, Schenectady, NY (US)

Correspondence Address: BEUSSE BROWNLEE WOLTER MORA & MAIRE, P. A., 390 NORTH ORANGE AVENUE, SUITE 2500, ORLANDO, FL, 32801, US

(21) Appl. No.: 10/748,587

(22) Filed: Dec. 30, 2003

(51) Int. Cl. H01L 31/00

(52) U.S. Cl. 136/293; 136/244

(57) ABSTRACT

A transformerless photovoltaic system that may benefit from inverter topologies more suitable for ripple current cancellation techniques is provided. In one exemplary embodiment, the system may combine basic modules of straightforward inverter topologies to meet requirements for higher power applications and may comprise a bipolar photovoltaic array, and a full-bridge inverter electrically coupled to the bipolar photovoltaic array. The full bridge inverter may comprise first and second inverter legs that may be arranged to energize two phases of a grid electrically coupled to the photovoltaic system. In one exemplary embodiment, switching signals applied to switching devices in each of the first and second inverter legs may be adjusted relative to one other to reduce ripple current therein, thereby reducing the size of components used by the system.

This invention was made with U.S. Government support through Government Contract Number 55792 awarded by the Department of Energy, and, in accordance with the terms set forth in said contract, the U.S. Government may have certain rights in the invention.

### BACKGROUND OF THE INVENTION

Electrical codes (such as the National Electrical Code—NEC) that may be applicable to photovoltaic systems in some cases may require that one side of a photovoltaic array be grounded. See for example, NEC Article 690. This requirement may present a problem when interfacing, for example, with a 120/240 Vac utility grid that also requires its neutral point to be grounded. In order to ground both the array and the utility as required by code, photovoltaic systems have commonly employed an isolation transformer.

In the case of a typical 60-Hz or 50-Hz power conversion application, the isolation transformer may usually comprise a device of substantial bulk and weight placed between the grid and the photovoltaic array to allow the grounding of both the array and the grid. The need of such an isolation transformer adds to the cost of a photovoltaic system and can lead to significant energy losses, thus decreasing the efficiency of the power conversion process.

FIG. 1 is a schematic view of one known photovoltaic system 10 comprising an inverter 12 configured in a half-bridge inverter topology that, for example, supplies a 120-Vac utility-compatible signal without using any isolation transformer. A split three-wire photovoltaic array 18 may be configured as shown in FIG. 1. This type of photovoltaic array connection is commonly referred to as a bipolar connected array. That is, a photovoltaic array that has two outputs, such as outputs 20 and 22, each having opposite polarity relative to a common reference point, or center tap 25. This circuit configuration essentially allows using one-half of the photovoltaic array to generate a positive half cycle of the ac output signal relative to ground, and the other half of the photovoltaic array is used to generate a negative half cycle of the ac output signal relative to ground. A filter 26, such as comprising a capacitor 28 and an inductor 30, is coupled to filter out high frequency components (e.g., switching frequency components) that may be present in current passed by the switching devices 24. Because a half bridge topology typically supplies power to just a single phase of the grid (e.g., a single 120-Vac line), in a practical implementation, the power rating is likely to be limited to an upper limit in the order of 2500 Watts.

FIG. 4 is a schematic view of another known photovoltaic system that also uses a half-bridge inverter topology. In this case, a multi-level inverter 200 comprises four switching devices 202 per inverter leg in lieu of two switching devices. Clamping diodes (D1 and D2) ensure that none of the switching devices 202 carries more than the voltage generated by any one of the photovoltaic sources that make up the bipolar array (e.g., photovoltaic sources Va1 or Va2).

It has been shown that multi-level inverter topologies alleviate the need of using switching devices with high-voltage ratings by reducing the voltage stress across the switching devices to approximately half of the input voltage from the dc voltage source. For readers desirous of background information regarding operation of multi-level inverters reference is made to the following two articles: 1) Article titled “A High-Power-Density DC/DC Converter For High-Power Distributed Power Systems” by Canales, F.; Barbosa, P.; Aguilar, C.; and Lee, F. C., presented at Power Electronics Specialist, 2003. PESC '03. IEEE 34th Annual Conference, held Jun. 15-19, 2003, and published at conference record Vol.1, pages: 11-18; and 2) Article titled “Wide Input Voltage And Load Output Variations Fixed-Frequency ZVS DC/DC LLC Resonant Converter For High-Power Applications” by Canales, F.; Barbosa, P.; Lee, F. C., presented at Industry Applications Conference, 2002. 37th IAS Annual Meeting, held 13-18 Oct. 2002 and published at conference record Vol.4, pages: 2306-2313. Each of the aforementioned articles is herein incorporated by reference in its entirety.

Once again, because a half bridge topology typically supplies power to just a single phase of the grid (e.g., a single 120-Vac line), in a practical implementation, the power rating is likely to be limited to an upper limit in the order of 2500 Watts. However, for relatively higher power applications (such as may range from about 3 Kilowatts (kW) to about 5 kW) it may be desirable to supply power to both sides of the ac ground.

Thus, it would be desirable to combine modules of the above-described transformerless inverter topologies to meet such requirements for higher power applications. It would be further desirable to use inverter topologies more suitable for ripple current cancellation techniques, thereby leading to smaller and less expensive filter components.

### BRIEF DESCRIPTION OF THE INVENTION

Generally, the present invention fulfills the foregoing needs by providing, in one aspect thereof, a transformerless photovoltaic system comprising a bipolar photovoltaic array and a full-bridge inverter electrically coupled to the bipolar photovoltaic array. The full bridge inverter may comprise first and second legs arranged to energize at least two phases of a grid electrically coupled to the photovoltaic system, wherein switching signals applied to switching devices in each of the first and second legs may be adjusted relative to one other to reduce ripple current therein.

In another aspect thereof, the present invention further fulfills the foregoing needs by providing a photovoltaic system comprising a photovoltaic array and a full-bridge inverter electrically coupled to the photovoltaic array. The full bridge inverter comprises first and second legs arranged to energize at least two phases of a grid electrically coupled to the photovoltaic system. The full-bridge inverter may further comprise a filter for removing ripple current that may be present in each of the first and second inverter legs. The filter may comprise a respective inductor in series circuit in each inverter leg and a common capacitor in a parallel circuit between the inverter legs.

### BRIEF DESCRIPTION OF THE DRAWINGS

The features and advantages of the present invention will become apparent from the following detailed description of the invention when read with the accompanying drawings in which:

FIG. 1 is a schematic view of one known photovoltaic system comprising a transformerless inverter configured in a half-bridge inverter topology;

FIG. 2 is a schematic view of an exemplary embodiment of a photovoltaic system comprising a transformerless inverter configured in a full-bridge inverter topology, suitable for higher power applications and for reducing ripple current through appropriate inverter control and ripple current cancellation techniques;

FIG. 3 is a schematic view of an exemplary embodiment of a photovoltaic system comprising a transformerless inverter configured in a full-bridge inverter topology, as may be coupled to an electrically floating photovoltaic array;

FIG. 4 is a schematic view of one known photovoltaic system comprising a transformerless inverter configured in a half-bridge multilevel inverter topology; and

FIG. 5 is a schematic view of an exemplary embodiment of a photovoltaic system comprising a transformerless inverter configured in a full-bridge multilevel inverter topology, suitable for higher power applications and for reducing ripple current through appropriate inverter control and ripple current cancellation techniques.

### DETAILED DESCRIPTION OF EXEMPLARY EMBODIMENTS

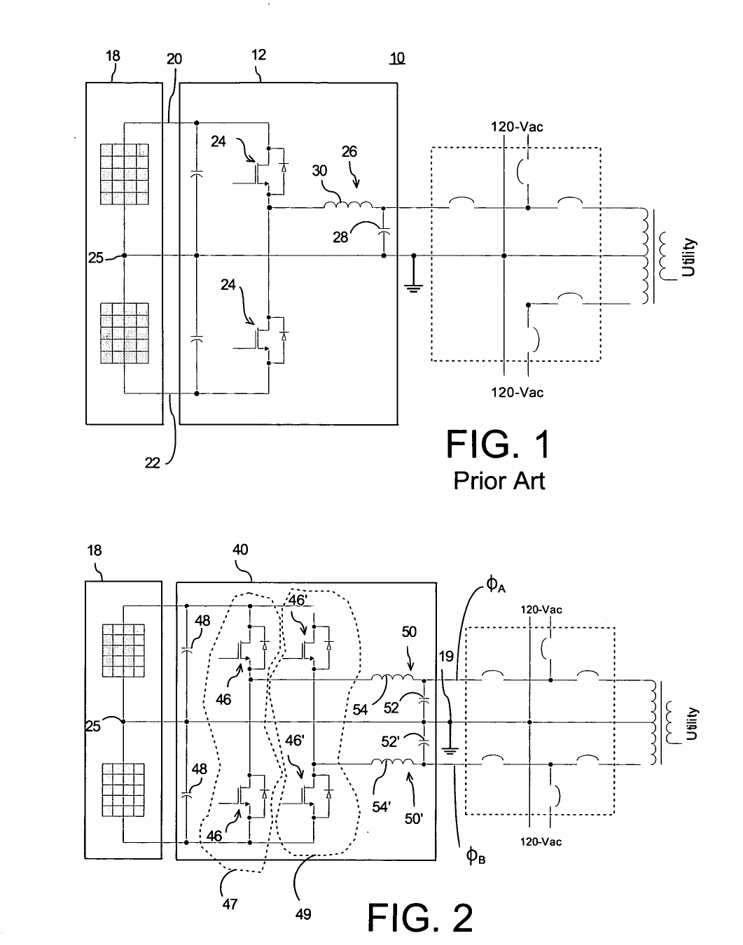

The fact that the half bridge topology illustrated in FIG. 1 supplies power just to one side of the 120-Vac line may be acceptable for relatively low power applications, such as less than approximately 2.5 kW. However, for relatively higher power applications (such as may range from about 3 kW to about 5 kW), it may be desirable to supply power to both sides of the ac ground, such as sides Ø_{A} and Ø_{B} in FIG. 2. For example, it may be desirable to supply power to a 120-Vac grid on both sides of neutral. This can be accomplished by employing an inverter 40 comprising a full bridge topology, such as may be obtained by coupling two half bridge inverters (one on each side of neutral) as shown in FIG. 2. In this embodiment, it can be seen that power can be injected in a balanced manner into both sides of neutral while maintaining both the bipolar photovoltaic array 18 and the grid neutral point at ground potential. That is, the array and the utility grid are both grounded at a common point 19 to meet applicable code requirements. This embodiment comprises innovatively coupling two of the half bridge circuits described in the context of FIG. 1 above—one for each 120-Vac source on either side of neutral. Thus, the grounded neutral can be maintained (as well as the grounded photovoltaic array) for either a grid connected or a stand-alone mode of operation.

The inventors of the present invention have innovatively recognized that a full bridge inverter topology is suitable for reduction of ripple current through appropriate inverter control (e.g., pulse-width-modulated (PWM) control) and ripple current cancellation techniques. For example, the switching signals applied to switching devices 46 and 46′ in each inverter leg, such as a first inverter leg 47 and a second inverter leg 49, can be phase shifted relative to one other to reduce the high-frequency ripple current in dc input capacitors 48. Respective filters 50 and 50′, such as comprising capacitors 52 and 52′ and inductors 54 and 54′, are coupled to filter out high frequency components (e.g., switching frequency components) that may be present in current passed by the switching devices 46 and 46′.

In order to accommodate a reasonably wide solar array voltage range variation (for example, 2.5 to 1), switching devices 46 and 46′, such as may comprise MOSFETs (Metal Oxide Semiconductor Field Effect Transistors), IGBTs (Insulated Gate Bipolar Transistors) or any other suitable switching device, should be appropriately rated to handle the expected voltage levels. For example, in one exemplary embodiment, it may be desirable to operate from a solar array that may vary from approximately 200 to approximately 550-Vdc. This exemplary range is consistent with the fact that the dc voltage (neutral to one end of the array) should be greater in magnitude than the peak of the ac line being supplied (e.g., the 120-Vac utility). Thus, in this example, the array voltage preferably should not fall much below 200-Vdc. In the foregoing exemplary voltage range, the highest solar array voltage is approximately 550-Vdc. Because of the split array configuration (to allow for common grounding), the total array voltage from negative to positive may range from approximately 400- to approximately 1100-Vdc. Thus, each switching device 46 and 46′ should be capable of blocking this maximum voltage and should be rated approximately no less than 1200 volts.

It should be appreciated that, since inverter 40 comprises just a single power stage and no transformer (which may save at least 2% efficiency), it is expected that inverter 40 will provide substantially efficient power conversion. The inverter switches 46 and 46′ may be actuated using, for example, PWM techniques well understood by those skilled in the art, in order to inject a sinusoidal current of utility quality into the grid. The photovoltaic system may also be used in a “stand-alone” mode. That is, supplying an ac load with no coupling to the utility.

Some exemplary characteristics of this embodiment may be:
Light weight and compactness due to elimination of isolation transformer.
High efficiency due to single power stage and no transformer losses.
Ease of installation due to lightweight and small size.
Ability to supply more power than a half-bridge approach.
Ability to reduce ripple current in dc capacitors through appropriate PWM control of inverter and ripple current cancellation techniques.

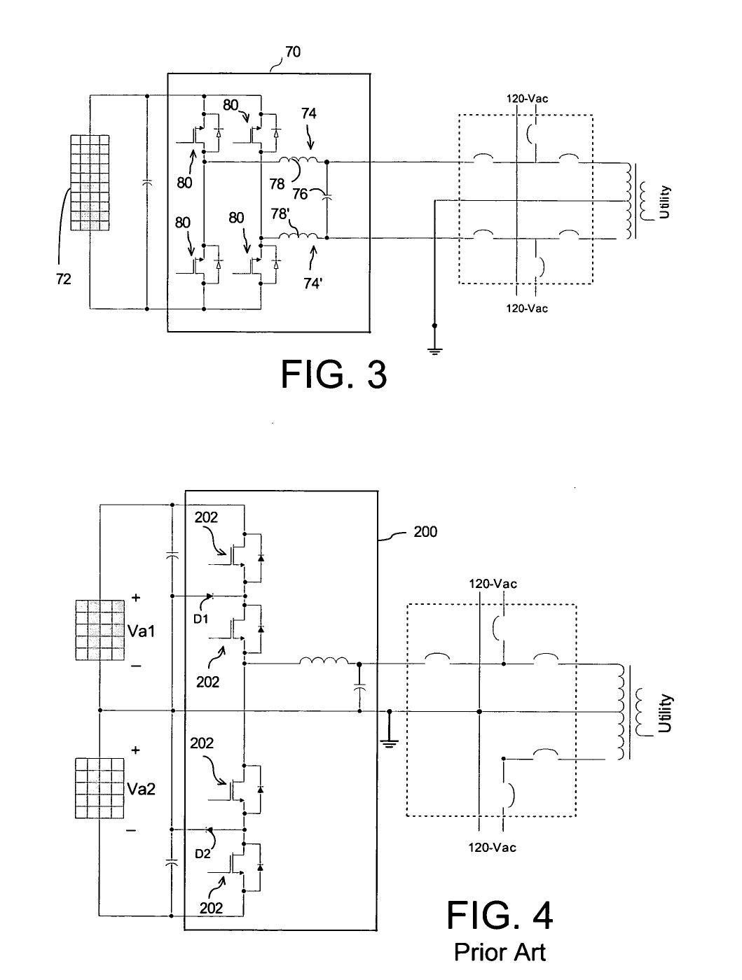

Additional aspects of the invention contemplate that, if in the future the requirement that one side of the array output be earth grounded is removed, then other inverter topologies become feasible. FIG. 3 shows a schematic of a full bridge inverter 70 coupled to an electrically floating photovoltaic array 72. Since the array 72 is floating, a straightforward full bridge inverter can be used to inject power directly into the utility grid, e.g., a 240-Vac grid. Note that this embodiment removes the need for a bipolar array. The circuit topology of FIG. 3 may be configured to supply power either to a 120-Vac grid or to a 240-Vac grid in a stand-alone mode. Respective filters 74 and 74′, such as comprising a common capacitor 76 and inductors 78 and 78′, are coupled to filter out high frequency components (e.g., switching frequency components) that may be present in current passed by the switching devices 80. Inductors 78 and 78′ allow providing balanced filtering of ripple currents relative to neutral and further provide an impedance that may protect the switching devices 80 from electrical spikes that may develop in the grid. For an exemplary 120-Vac configuration, this embodiment is likely to be very efficient since it may use relatively fast switching devices (e.g., IGBTs with ratings of 600-V) plus the avoidance of the isolation transformer. Thus, it would be a superior choice for relatively low power applications (e.g., <2 kW).

As described above in the context of FIG. 2, exemplary maximum voltages that the switching devices may have to block can exceed 1000 volts. For example, this may necessitate the use of switching devices with voltage ratings of at least 1200-V. As will be appreciated by those skilled in the art, this type of switching devices tends to have higher switching losses than their 600-V counterparts. Thus, it would be advantageous to provide circuitry that would allow implementation of a transformerless approach for a relatively higher power application while employing switching devices with relatively lower voltage ratings, e.g., 600-V IGBTs.

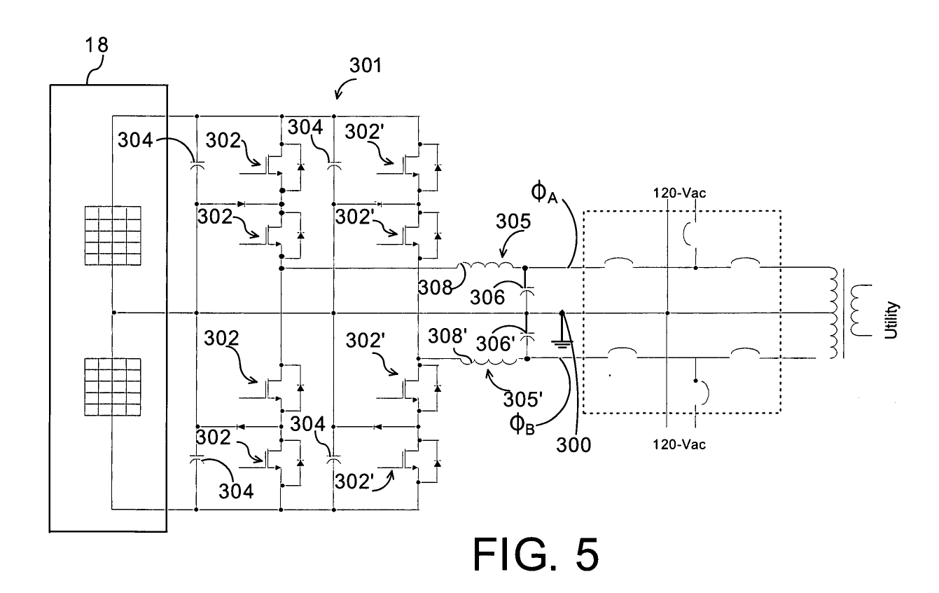

More specifically, FIG. 5 is a schematic view of a full bridge topology that advantageously makes use of the half-bridge multi-level inverter of FIG. 4. This embodiment is configured to inject power to both phases of the grid, e.g., both sides of a 120-Vac grid. The photovoltaic array as well as the grid may be grounded at a single point 300 to meet existing codes without the need for any isolation transformer. This embodiment innovatively couples in a full bridge multi-level inverter 301 two half bridge inverters as described above in the context of FIG. 4. It is noted that in a full bridge topology the high frequency switching of the two half bridges may be synchronized relative to one another (e.g., phase shifted) to obtain ripple current cancellation in the dc filter capacitors 304. Respective filters 305 and 305′, such as comprising capacitors 306 and 306′ and inductors 308 and 308′, are coupled to filter out high frequency components (e.g., switching frequency components) that may be present in the current passed by the switching devices 302 and 302′. Since this inverter may inject power to both 120-Vac sides of neutral, it is suitable for relatively high power applications.

Thus, faster switching devices, such as 600-V IGBTs, can be used in the transformerless embodiment of FIG. 5. These lower voltage rated switching devices are conducive to overall switching loss reduction that more than makes up for any incremental conduction loss due to the coupling of two such switching devices in series per each inverter leg. For example, even though there are two devices in series, the combined forward voltage drop of each 600-V IGBT is comparable to the forward voltage drop of a single 1200-V IGBT. Furthermore, the cost of the 600-V devices is comparable to the cost of a 1200-V device. Because the switching losses are lower, the inverter may be operated at higher switching frequency and this in turn leads to smaller and less expensive filter circuits.

Exemplary characteristics of this embodiment may be as follows:
Light weight and compactness due to elimination of isolation transformer.
High efficiency due to single power stage and no transformer losses.
Ease of installation due to lightweight and small size.
Array and utility can be grounded at a single point.
Fast switching (low switching losses), 600 volt IGBTs and diodes can be used.
Ability to supply more power than a half-bridge approach.
Production of 240/120 center tapped utility voltage or current.
Smaller components for filters if inverter is operated at higher frequency or ripple current cancellation techniques are employed.

While the preferred embodiments of the present invention have been shown and described herein, it will be obvious that such embodiments are provided by way of example only. Numerous variations, changes and substitutions will occur to those of skill in the art without departing from the invention herein. Accordingly, it is intended that the invention be limited only by the spirit and scope of the appended claims.

1. A transformerless photovoltaic system comprising:
a bipolar photovoltaic array; and
a full-bridge inverter electrically coupled to said bipolar photovoltaic array, said full bridge inverter comprising first and second legs arranged to energize at least two phases of a grid electrically coupled to said photovoltaic system, wherein switching signals applied to switching devices in each of said first and second legs may be adjusted relative to one other to reduce ripple current therein.

2. The photovoltaic system of claim 1 wherein each of said first and second legs comprises two switching devices in a series circuit.

3. The photovoltaic system of claim 1 wherein each of said first and second legs comprises first and second pairs of switching devices in respective series circuit and a respective pair of clamping diodes coupled so that none of the first and second pairs of switching devices carries more than a voltage generated by any one photovoltaic sources that comprise the bipolar array.

4. The photovoltaic system of claim 3 wherein said first and second pairs of switching devices comprise switching devices having relatively lower voltage ratings, as compared to inverter legs comprising two switching devices in series circuit.

5. The photovoltaic system of claim 1 further comprising a respective filter comprising a capacitor and an inductor, each said filter coupled to one of said legs to remove ripple current therein.

6. The photovoltaic system of claim 5 wherein said switching devices may be operated at switching frequencies that are sufficiently high to enable reduction in the size of filter components.

7. The photovoltaic system of claim 1 comprising a power output in a range from about three kilowatts to about five kilowatts.

8. A photovoltaic system comprising:
a photovoltaic array; and
a full-bridge inverter electrically coupled to said photovoltaic array, said full bridge inverter comprising first and second legs arranged to energize at least two phases of a grid electrically coupled to said photovoltaic system, said full-bridge inverter further comprising a filter for removing ripple current that may be present in each of said first and second legs, said filter comprising a respective inductor in series circuit in each inverter leg and a common capacitor in a parallel circuit between said inverter legs.

9. The photovoltaic system of claim 8 wherein said photovoltaic array is electrically floating, and a neutral of the grid is electrically grounded.

10. The photovoltaic system of claim 8 wherein said photovoltaic array comprises a single source.
